(19) United States
(12) Patent Application Publication
(10) Pub. No.: US 2017/0032933 A1
(43) Pub. Date: Feb. 2, 2017

(54) Microwave Plasma Source and Plasma Processing Apparatus

(71) Applicant: TOKYO ELECTRON LIMITED, Tokyo (JP)

(72) Inventors: Tamotsu HARADA, Nirasaki City (JP); Emiko HARA, Nirasaki City (JP); Taro IKEDA, Nirasaki City (JP)

(21) Appl. No.: 15/217,187

(22) Filed: Jul. 22, 2016

(30) Foreign Application Priority Data
Jul. 31, 2015 (JP) 2015-152169

(51) Int. Cl. H01J 37/32

(52) U.S. Cl. CPC H01J 37/3244; H01J 37/32311; H01J 37/32715; H01J 37/32733; H01J 37/32834; H01J 37/3222; H01J 2237/332; H01J 2237/334

(57) ABSTRACT

There is provided a microwave plasma source for radiating microwaves into a chamber of a plasma processing apparatus to generate surface wave plasma, including: a plurality of microwave radiation mechanisms provided in a ceiling wall of the chamber and configured to radiate microwaves into the chamber; and a perforated plate provided in a high electric field formation region used as a high electric field region when the microwaves are radiated from microwave radiation surfaces of the microwave radiation mechanisms into the chamber and which exists just below the microwave radiation surfaces. The perforated plate has a function of confining surface waves formed just below the microwave radiation surfaces when the microwaves are radiated from the microwave radiation mechanism, in a space surrounded by the microwave radiation surfaces and the perforated plate, and a function of keeping high a power absorption efficiency of plasma generated in the space.

### CROSS-REFERENCE TO RELATED APPLICATION

This application claims the benefit of Japanese Patent Application No. 2015-152169, filed on Jul. 31, 2015, in the Japan Patent Office, the disclosure of which is incorporated herein in its entirety by reference.

### TECHNICAL FIELD

The present disclosure relates to a microwave plasma source and a plasma processing apparatus using the same.

### BACKGROUND

A plasma process is a technique essential for manufacture of semiconductor devices. With recent demands for high integration and high speed of LSI, a design rule of semiconductor devices has been finer and finer and the size of semiconductor wafers has been increased. Accordingly, there is a need for a plasma processing apparatus to cope with such fineness and increase in size.

However, parallel-plate type or inductively-coupled plasma processing apparatuses have difficulties in plasma processing large diameter semiconductor wafers with uniformity and at a high speed.

For the purpose of avoiding such difficulties, attention has been paid to a RLSA® microwave plasma apparatus which is capable of uniformly forming a surface wave plasma with high density and at a low electron temperature.

In the RLSA® microwave plasma processing apparatus, a radial line slot antenna, i.e., a planar slot antenna having a plurality of slots formed in a predetermined pattern, as a microwave radiation antenna which emits microwaves for generating a surface wave plasma, is provided in the upper portion of a chamber. The microwaves guided from a microwave source are radiated from the slots of the antenna and are radiated into the chamber kept at vacuum through a dielectric microwave transmission plate provided below the antenna. By an electric field of the microwaves, a surface wave plasma is generated in the chamber and target objects such as semiconductor wafers are processed by the surface wave plasma.

In the case where plasma distribution is adjusted in such a RLSA® microwave plasma apparatus, a plurality of antennas differing in slot shape, pattern and the like need to be prepared and replaced. This task may be quite onerous.

In contrast, in the related art, there is disclosed a plasma source in which one microwave is divided into a plurality of microwaves and in which a plurality of microwave radiation mechanisms each provided with a planar antenna described above and a tuner for performing impedance matching and configured to radiate microwaves into a chamber is installed. In the plasma source, the microwaves radiated from the plurality of microwave radiation mechanisms are guided into the chamber and are spatially synthesized in the chamber.

By spatially synthesizing the microwaves using the plurality of microwave radiation mechanisms, it is possible to individually adjust phases or magnitudes of the microwaves radiated from the respective microwave radiation mechanisms. This makes it possible to relatively easily adjust the plasma distribution.

In the case where the microwaves are spatially synthesized by radiating the microwaves from the plurality of microwave radiation mechanism into the chamber, an abnormal electrical discharge may be generated under an actual process condition. Thus, there may be generated a phenomenon that the plasma is destabilized. Furthermore, it is sometimes the case that a plasma ignitability is lowered and an ignition power is increased.

### SUMMARY

Some embodiments of the present disclosure provide a microwave plasma source in which an abnormal electrical discharge is difficult to generate under a wide process condition even if the microwave plasma source includes a plurality of microwave radiation mechanisms and in which a plasma ignitability is good, and a plasma processing apparatus using the same.

According to one embodiment of the present disclosure, there is provided a microwave plasma source for radiating microwaves into a chamber of a plasma processing apparatus to generate surface wave plasma, including: a plurality of microwave radiation mechanisms provided in a ceiling wall of the chamber and configured to radiate microwaves into the chamber; and a perforated plate provided in a high electric field formation region which becomes a high electric field region when the microwaves are radiated from microwave radiation surfaces of the microwave radiation mechanisms into the chamber and which exists just below the microwave radiation surfaces, the perforated plate having a plurality of holes formed therein, the perforated plate set at a ground potential and made of an electrically conductive material, wherein the perforated plate has a function of confining surface waves formed just below the microwave radiation surfaces when the microwaves are radiated from the microwave radiation mechanism, in a space surrounded by the microwave radiation surfaces and the perforated plate and configured to become the high electric field region, and a function of keeping high a power absorption efficiency of plasma generated in the space.

According to another embodiment of the present disclosure, there is provided a plasma processing apparatus, including: a chamber configured to accommodate a target substrate; a mounting table configured to mount the substrate thereon within the chamber; a gas supply mechanism configured to supply a gas into the chamber; and a microwave plasma source configured to radiate microwaves into the chamber to form surface wave plasma, the plasma processing apparatus configured to perform a plasma process on the target substrate using the surface wave plasma. The microwave plasma source includes: a plurality of microwave radiation mechanisms provided in a ceiling wall of the chamber and configured to radiate microwaves into the chamber; and a perforated plate provided in a high electric field formation region which becomes a high electric field region when the microwaves are radiated from microwave radiation surfaces of the plurality of microwave radiation mechanisms into the chamber and which exists just below the microwave radiation surfaces. The perforated plate has a plurality of holes form therein. The perforated plate is set at a ground potential and is made of an electrically conductive material. The perforated plate has a function of confining surface waves formed just below the microwave radiation surfaces when the microwaves are radiated from plurality of the microwave radiation mechanism, in a space surrounded by the microwave radiation surfaces and the perforated plate and configured to become the high electric field region, and a function of keeping high a power absorption efficiency of plasma generated in the space.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view illustrating a schematic configuration of a plasma processing apparatus according to a first embodiment of the present disclosure.

FIG. 2 is a block diagram illustrating a configuration of a microwave plasma source used in the plasma processing apparatus shown in FIG. 1.

FIG. 3 is a plan view schematically illustrating the arrangement of microwave radiation mechanisms in the microwave plasma source used in the plasma processing apparatus shown in FIG. 1.

FIG. 4 is a sectional view illustrating a microwave radiation plate and microwave radiation mechanisms in the microwave plasma source of the plasma processing apparatus shown in FIG. 1.

FIG. 5 is a view illustrating a relationship between a distance Z from a microwave radiation surface found by an electromagnetic field simulation and an electric field intensity.

FIG. 6 is a view illustrating a state in which an insulating coating is provided inside an outer peripheral wall of a microwave radiation plate and on an upper surface of a perforated plate.

FIG. 7 is a sectional view illustrating the microwave radiation mechanism.

FIG. 8 is a transversal cross-sectional view taken along line A-A′ in FIG. 7, illustrating a power feeding mechanism of the microwave radiation mechanism.

FIG. 9 is a transversal cross-sectional view taken along line B-B′ in FIG. 7, illustrating a slug and a sliding member in the microwave radiation mechanism

FIGS. 10A and 10B are views showing the presence or absence of abnormal electrical discharge in the case where a surface wave plasma is formed by using the plasma processing apparatus shown in FIG. 1 and provided with a perforated plate and a plasma processing apparatus not provided with a perforated plate and by changing a microwave power and the internal pressure of a chamber, FIG. 10A showing a case where the perforated plate is provided and FIG. 10B showing a case where the perforated plate is not provided.

FIG. 11 is a view showing an ignition power (plasma-igniting power) when the internal pressure of the chamber is changed by using the plasma processing apparatus shown in FIG. 1 and provided with a perforated plate and a plasma processing apparatus not provided with a perforated plate.

FIG. 12 is a sectional view illustrating a schematic configuration of a plasma processing apparatus according to a second embodiment of the present disclosure.

FIG. 13 is a sectional view of the plasma processing apparatus taken along line C-C′ in FIG. 12.

FIGS. 14 A and 14B are views showing evaluation results of an electron density distribution in the diametrical direction of a chamber in the case where only a central microwave radiation mechanism is turned on by using the plasma processing apparatus shown in FIG. 1 and not provided with a partition wall and the plasma processing apparatus shown in FIG. 12 and provided with a partition wall and in the case where only six peripheral microwave radiation mechanisms are turned on by using the plasma processing apparatus shown in FIG. 1 and not provided with a partition wall and the plasma processing apparatus shown in FIG. 12 and provided with a partition wall.

FIG. 15 is a sectional view illustrating another arrangement of the partition walls.

FIGS. 16A and 16B are views illustrating other arrangement examples of the microwave radiation mechanisms.

FIGS. 17A and 17B are views illustrating examples in which partition walls are provided in the microwave radiation mechanisms shown in FIGS. 16A and 16B.

### DETAILED DESCRIPTION

Reference will now be made in detail to various embodiments, examples of which are shown in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

First, descriptions will be made on a first embodiment.

### Configuration of Plasma Processing Apparatus

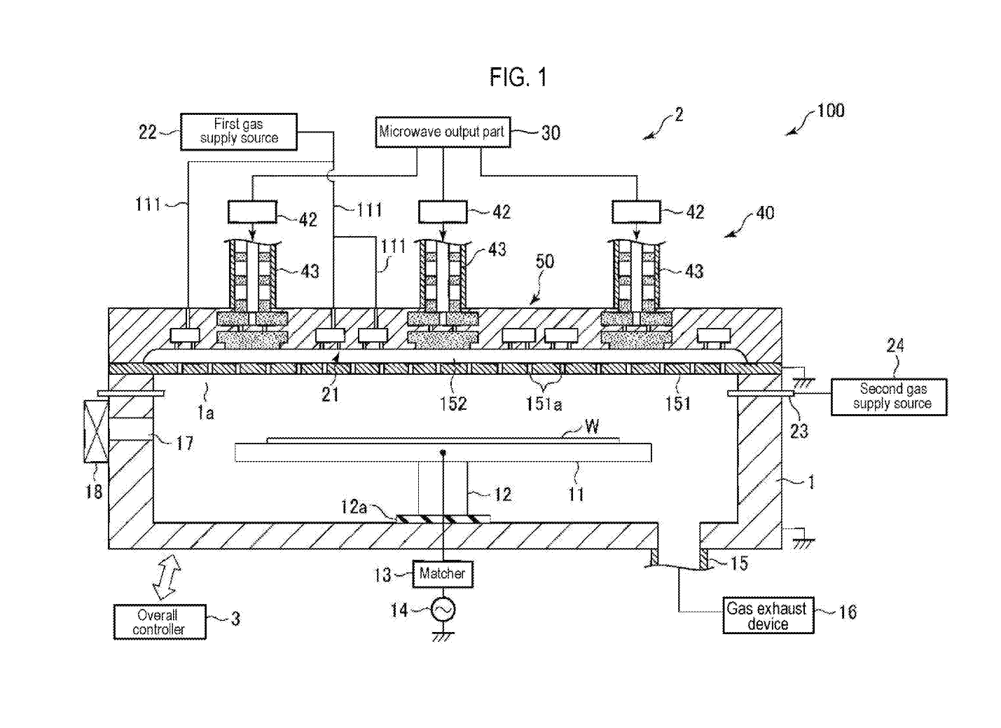

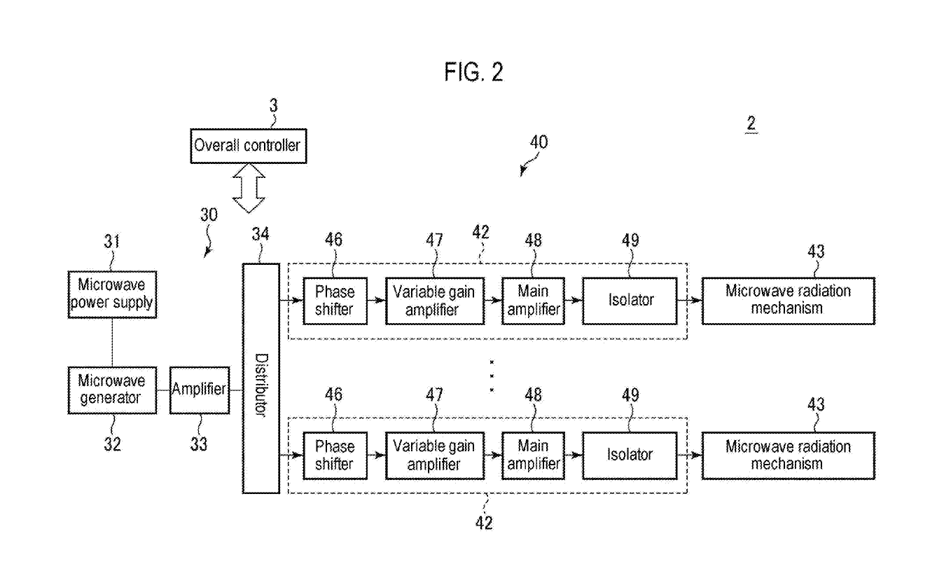

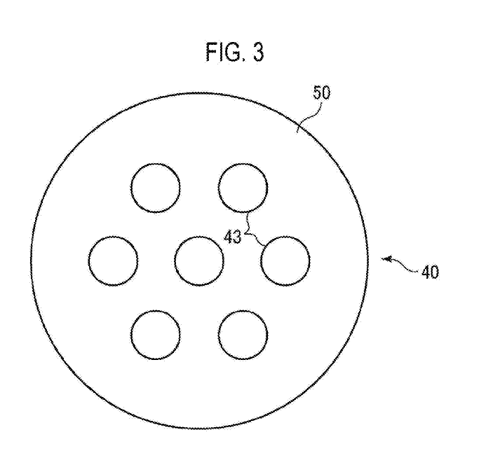

FIG. 1 is a sectional view illustrating a schematic configuration of a plasma processing apparatus according to a first embodiment of the present disclosure. FIG. 2 is a block diagram illustrating a configuration of a microwave plasma source used in the plasma processing apparatus shown in FIG. 1. FIG. 3 is a plan view schematically illustrating the arrangement of microwave radiation mechanisms in the microwave plasma source used in the plasma processing apparatus shown in FIG. 1.

A plasma processing apparatus 100 is provided to perform a predetermined plasma process with respect to wafers using a surface wave plasma generated by a microwave. An example of the plasma process may include a film forming process or an etching process.

The plasma processing apparatus 100 includes a grounded airtight cylindrical chamber 1 made of a metal material such as aluminum or stainless steel, and a microwave plasma source 2 configured to generate a surface wave plasma inside the chamber 1 by introducing a microwave into the chamber 1. An opening 1a is formed in an upper portion of the chamber 1. The microwave plasma source 2 is installed to face the interior of the chamber 1 through the opening 1a.

In addition, the plasma processing apparatus 100 includes an overall control part 3 equipped with a microprocessor. The overall control part 3 is configured to control respective components of the plasma processing apparatus 100. The overall control part 3 includes a storage part storing a process sequence of the plasma processing apparatus 100 and process recipes as control parameters, an input means, a display and so on, and can perform a predetermined control according to a selected process recipe.

A susceptor (mounting table) 11 configured to horizontally support a semiconductor wafer W (hereinafter simply referred to as a “wafer W”) as a workpiece is installed inside the chamber 1. The susceptor 11 is supported by a cylindrical support member 12 installed upright on the center of the bottom of the chamber 1 via an insulating member 12a. The susceptor 11 and the support member 12 are made of, for example, metal such as aluminum whose surface is alumite-treated (anodized), an insulating material (e.g., ceramics) having a high frequency electrode formed therein, or the like.

In addition, although not shown, the susceptor 11 includes an electrostatic chuck for electrostatically adsorbing the wafer W, a temperature control mechanism, a gas passage through which a heat transfer gas is supplied onto a rear surface of the wafer W, lift pins configured to move up and down to transfer the wafer W, and so on. Further, the susceptor 11 is electrically coupled to an RF (Radio Frequency) bias power supply 14 via a matching device 13. When RF power is supplied from the RF bias power supply 14 to the susceptor 11, ions in plasma are retracted to the wafer W side. The RF bias power supply 14 may be omitted depending on characteristics of the plasma process. In this case, even when the susceptor 11 is formed of an insulating member made of ceramics such as MN or the like, no electrode is required.

An exhaust pipe 15 is connected to the bottom of the chamber 1. The exhaust pipe 15 is connected to an exhaust device 16 including a vacuum pump. The exhaust device 16 is actuated to exhaust the chamber 1, so that the interior of the chamber 1 can be quickly depressurized up to a predetermined degree of vacuum. A loading/unloading port 17 through which the wafer W is loaded into and unloaded from the chamber 1, and a gate valve 18 for opening/closing the loading/unloading port 17, are installed in a side wall of the chamber 1.

The microwave plasma source 2 includes a microwave output part 30 configured to output microwaves through a plurality of paths, a microwave transmission/radiation part 40 configured to transmit the microwaves outputted from the microwave output part 30 and to radiate the microwaves into the chamber 1, a microwave radiation plate 50 which constitutes a ceiling wall of the chamber 1 and has a microwave radiation surface, and a perforated plate 151 provided just below the microwave radiation plate 50 so as to face the microwave radiation plate 50. The perforated plate 151 is made of an electrically conductive material and is provided with a plurality of holes 151a. The perforated plate 151 is supported on the sidewall of the chamber 1 and is grounded. A minute space 152 to be described below is formed between the lower surface (used as the microwave radiation surface) of the microwave radiation plate 50 and an upper surface of the perforated plate 151.

A first gas introduction part 21 having a shower structure is provided in the microwave radiation plate 50. A first gas such as a plasma-generating gas, for example, an Ar gas, or a gas to be decomposed with high energy, for example, an O₂ gas or an N₂ gas, is supplied from a first gas supply source 22 to the first gas introduction part 21. The first gas is introduced from the first gas introduction part 21 into the chamber 1.

A second gas introduction part 23 having an annular shape is provided under the perforated plate 151 and above the susceptor 11 within the chamber 1. During a plasma process such as a film forming process or an etching process, a process gas to be supplied without decomposition as far as possible, for example, a second process gas such as, SiH₄ or C₅F₈, is supplied from a second gas supply source 24 to the second gas introduction part 23. Different types of gases adapted for the plasma process may be used as the gases supplied from the first gas supply source 22 and the second gas supply source 24.

Next, a detailed structure of the microwave plasma source 2 will be described. As described above, the microwave plasma source 2 includes the microwave output part 30, the microwave transmission/radiation part 40, the microwave radiation plate 50 and the perforated plate 151.

As shown in FIG. 2, the microwave output part 30 includes a microwave power supply 31, a microwave oscillator 32, an amplifier 33 for amplifying an oscillated microwave, and a distributor 34 for distributing the amplified microwave into a plurality of microwaves.

For example, the microwave oscillator 32 PLL-oscillates a microwave having a predetermined frequency (e.g., 860 MHz). The distributor 34 distributes the microwave amplified in the amplifier 33 while taking an impedance matching between an input side and an output side such that as little loss as possible occurs. Instead of 860 MHz, the microwave may have a frequency selected from a wide frequency ranging from 700 MHz to 3 GHz, for example, 915 MHz.

The microwave transmission/radiation part 40 includes a plurality of amplifier parts 42 configured to mainly amplify the microwaves distributed by the distributor 34, and a plurality of microwave radiation mechanisms 43 provided corresponding to the amplifier parts 42. As shown in FIG. 3, the microwave transmission/radiation part 40 includes seven amplifier parts 42 and seven microwave radiation mechanisms 43. Six of the seven microwave radiation mechanisms 43 are provided in a peripheral portion of the microwave radiation plate 50 having a circular shape along a circumferential direction and one of the seven microwave radiation mechanisms 43 is provided in a central portion of the microwave radiation plate 50.

As shown in FIG. 2, the amplifier parts 42 of the microwave transmission/radiation part 40 are configured to amplify the microwaves distributed by the distributor 34 and to guide the same to the respective microwave radiation mechanisms 43. Each of the amplifier parts 42 includes a phase shifter 46, a variable gain amplifier 47, a main amplifier 48 that constitutes a solid state amplifier, and an isolator 49.

The phase shifter 46 is configured to change a phase of a microwave and can adjust the phase to modulate a radiation characteristic. For example, the phase shifter 46 can change the phase of a respective microwave corresponding to each of the microwave radiation mechanisms to control directionality, thus changing a plasma distribution. In addition, the phase shifter 46 can shift the phase by 90 degrees between adjacent microwave radiation mechanisms to obtain a circularly-polarized wave. Further, the phase shifter 46 can adjust a delay characteristic between components in an amplifier such that the phase shifter 46 is used for the purpose of spatial synthesis within the microwave radiation mechanisms. However, the phase shifter 46 may be omitted if such modulation of the radiation characteristic and the adjustment of the delay characteristic between components in the amplifier are not required.

The variable gain amplifier 47 is to adjust a power level of microwave to be inputted to the main amplifier 48, thus adjusting a plasma intensity. By changing the variable gain amplifier 47 for each antenna module, it is possible to allow a distribution to be produced in generated plasma.

The main amplifier 48 constituting a solid state amplifier may be configured to include, for example, an input matching circuit, a semiconductor amplifying element, an output matching circuit and a high Q resonance circuit.

The isolator 49 is used to isolate a reflected microwave which is reflected at a slot antenna (to be described later) and orients to the main amplifier 48, and includes a circulator and a dummy load (coaxial terminator). The circulator guides the reflected microwave to the dummy load. The dummy load converts the reflected microwave guided by the circulator into heat.

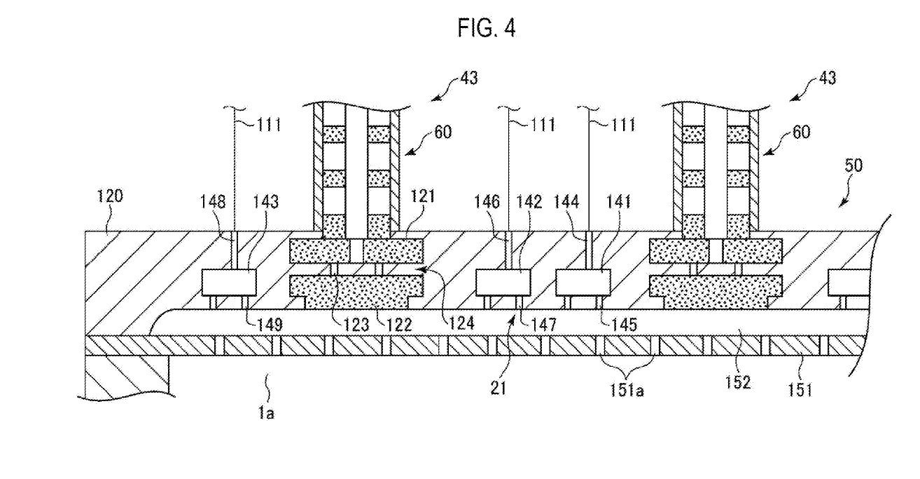

As shown in FIG. 4, each of the microwave radiation mechanisms 43 includes a tuner 60. The tuner 60 has a function of transmitting the microwaves supplied from the respective amplifier part 42 and matching the impedance. The tuner 60 is installed on the upper surface of the microwave radiation plate 50.

The microwave radiation plate 50 includes a metal-made main body portion 120. A slow-wave member 121 and a microwave transmission member 122, both of which constitute a portion of each of the microwave radiation mechanisms 43, are fitted to upper and lower surfaces of the main body portion 120. The slow-wave member 121 and the microwave transmission member 122 are made of a dielectric material and are formed in a disc shape. The slow-wave member 121 and the microwave transmission member 122 are provided at a position corresponding to the tuner 60. Slots 123 are formed in a portion between the slow-wave member 121 and the microwave transmission member 122 in the main body portion 120. The portion between the slow-wave member 121 and the microwave transmission member 122 in which the slots 123 are formed, makes up a planar slot antenna 124 which is a portion of the respective microwave radiation mechanism 43.

The slow-wave member 121 has a dielectric constant higher than a vacuum. The slow-wave member 121 is made of, for example, quartz, ceramics, a fluorine-based resin such as polytetrafluoroethylene or the like, or a polyimide-based resin. Since a microwave wavelength becomes longer in a vacuum, the slow-wave member 121 serves to shorten the microwave wavelength, thereby making the antenna small.

The microwave transmission member 122 is made of a dielectric material which transmits microwaves. The microwave transmission member 122 has a function of forming a uniform surface wave plasma in a circumferential direction. Similar to the slow-wave member 121, the microwave transmission member 122 may be made of, for example, quartz, ceramics, a fluorine-based resin such as polytetrafluoroethylene or the like, or a polyimide-based resin.

As shown in FIG. 4, the slots 123 are respectively formed to penetrate from a lower surface of the slow-wave member 121 up to an upper surface of the microwave transmission member 122 in the portion between the slow-wave member 121 and the microwave transmission member 122 inside the main body 120. The slots 123 are formed in a shape capable of achieving desired microwave radiation characteristics, for example, an arc shape or a circumferential shape. Portions around the slots 123 between the main body portion 120 and the microwave transmission member 122 are sealed by seal rings (not shown). Thus, the microwave transmission member 122 covers and seals the slots 123, thereby serving as a vacuum seal.

The slots 123 may be filled with a dielectric, although they may be vacuous. When the slots 123 are filled with the dielectric, a microwave effective wavelength can be shortened and the slots can be formed to be thinner. An example of the dielectric with which the slots 123 are filled may include quartz, ceramics, a fluorine-based resin such as polytetrafluoroethylene, or a polyimide-based resin.

The first gas introduction part 21 described above is provided in the main body portion 120 of the microwave radiation plate 50. The first gas introduction part 21 includes an inner gas diffusion space 141 annularly formed around the central microwave radiation mechanism 43, a middle gas diffusion space 142 annularly formed outside the inner gas diffusion space 141 and inside the arrangement region of the peripheral microwave radiation mechanisms 43, and an outer gas diffusion space 143 annularly formed outside the arrangement region of the peripheral microwave radiation mechanisms 43. The inner gas diffusion space 141, the middle gas diffusion space 142 and the outer gas diffusion space 143 are concentrically formed. A gas introduction hole 144 extending from the upper surface of the main body portion 120 is formed up to an upper surface of the inner gas diffusion space 141. A plurality of gas discharge holes 145 leading to the lower surface of the main body portion 120 is formed from an lower surface of the inner gas diffusion space 141. In the meantime, a gas introduction hole 146 extending from the upper surface of the main body portion 120 is formed up to an upper surface of the middle gas diffusion space 142. A plurality of gas discharge holes 147 leading to the lower surface of the main body portion 120 is formed from a lower surface of the middle gas diffusion space 142. In addition, a gas introduction hole 148 extending from the upper surface of the main body portion 120 is formed up to an upper surface of the outer gas diffusion space 143. A plurality of gas discharge holes 149 leading to the lower surface of the main body portion 120 is formed from a lower surface of the outer gas diffusion space 143. Gas supply pipes 111 through which the first gas is supplied from the first gas supply source 22 are connected to the gas introduction holes 144, 146 and 148.

In some embodiments, an example of the metal constituting the main body portion 120 may include a metal having high heat conductivity such as aluminum or copper.

The microwaves transmitted as TEM waves through the tuner 60 are introduced into the microwave radiation plate 50 and are transmitted through the slow-wave member 121. Thereafter, the microwaves are transmitted to the slots 123 of the slot antenna 124 and are converted to a mode of TE waves. Subsequently, the microwaves are transmitted through the microwave transmission member 122 and are radiated into the chamber 1, whereby surface waves are formed on the surface of the microwave transmission member 122. The first gas introduced from the first gas introduction part 21 into the chamber 1 is converted to plasma by the surface waves. Thus, a surface wave plasma is generated in the space of the chamber 1.

Accordingly, the lower surface of the microwave transmission member 122 becomes a microwave radiation surface. The lower surface of the main body portion 120 of the microwave radiation plate 50 is flush with the lower surface of the microwave transmission member 122 so that the lower surface of the microwave radiation plate 50 has the microwave radiation surface.

In this case, an electric field intensity within the chamber 1 when the microwaves are radiated from the microwave radiation surface is largest on the lower surface of the microwave transmission member 122, i.e., the microwave radiation surface, and is sharply reduced as the distance from the microwave radiation surface grows larger. That is to say, a portion defined just below the microwave radiation plate 50 including the microwave radiation surface becomes a high electric field formation region in which a high electric field is formed during the radiation of microwaves.

The perforated plate 151 provided just below the microwave radiation plate 50 is disposed in the high electric field formation region. The microwave radiation plate 50 has an outer peripheral wall which is disposed in the periphery of the lower surface of the microwave radiation plate 50 including the microwave radiation surface so as to constitute a portion of the downwardly-extending sidewall of the chamber 1. The perforated plate 151 is installed between the outer peripheral wall of the microwave radiation plate 50 and the sidewall of the chamber 1. A space 152 is defined by the microwave radiation plate 50 and the perforated plate 151. When the microwaves are radiated from the microwave radiation mechanisms 43, the space 152 becomes a high electric field region so that plasma is formed in the space 152. That is to say, the space 152 becomes a plasma generation space.

The perforated plate 151 is set at a ground potential and has a function of keeping an electric power adsorption efficiency of the plasma at a high level by confining the surface waves, which are formed just below the microwave radiation surface when the microwaves are radiated from the microwave radiation surfaces of the microwave radiation mechanisms 43, in the space 152 serving as a high electric field region. In this way, by confining the surface waves in the space 152 and keeping the electric power adsorption efficiency of the plasma at a high level, stable electrical discharge is easily generated in the high electric field region. It is therefore possible to make it hard for an abnormal electrical discharge to occur, while improving the ignitability of plasma. In some embodiments, an example of a conductive material constituting the perforated plate 151 may include a metal having good electric conductivity such as aluminum or copper. In addition, a thickness of the perforated plate 151 may fall within a range of about 10 to 30 mm, and a diameter of each of the holes 151a of the perforated plate 151 may fall within a range of about 10 to 20 mm.

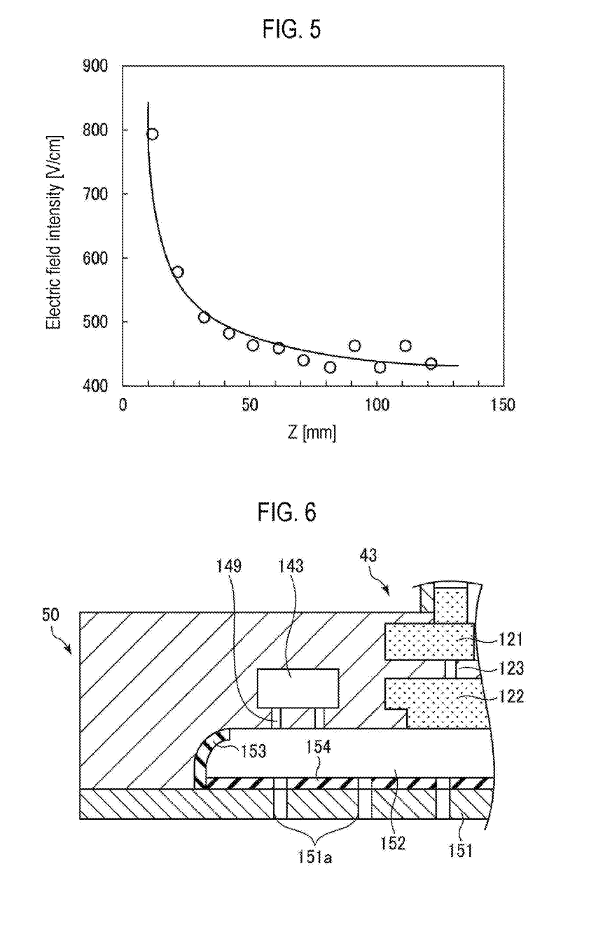

In some embodiments, in order for the perforated plate 151 to effectively achieve the aforementioned function, the distance from the microwave radiation surface to the upper surface of the perforated plate 151 may fall within a range of 2 to 30 mm, especially, a range of 2 to 20 mm. FIG. 5 is a view illustrating a relationship between the distance Z from the microwave radiation surface found by an electromagnetic field simulation and the electric field intensity. The simulation shows that a high electric field intensity is obtained in a region where the distance Z is 30 mm or less, especially, 20 mm or less. In the meantime, when the distance from the microwave radiation surface to the upper surface of the perforated plate 151 is too short, there is a possibility that the aforementioned effect is not effectively achieved. In view of this point, the distance from the microwave radiation surface to the upper surface of the perforated plate 151 was set to fall within a range of 2 mm or more.

The space 152 serving as a plasma generation space is surrounded by the microwave radiation plate 50 including the microwave radiation surface and the upper surface of the perforated plate 151. There is a possibility that radicals existing in the plasma are lost by metallic portions of lateral and bottom surfaces of the plasma generation space. To avoid this possibility, as shown in FIG. 6, an insulating coating 153 may be formed on an inner surface of the outer peripheral wall of the microwave radiation plate 50 corresponding to a lateral face of the chamber 1 in the space 152 used as the plasma generation space, and further, an insulating coating 154 may be formed on the upper surface of the perforated plate 151 which constitutes the lower surface of the plasma generation space. The insulating coatings 153 and 154 may be dielectric coatings formed by a thermal spraying or the like, or may be plate-shaped coatings such as quartz plates or the like. In addition, although both the insulating coatings 153 and 154 may be formed as shown in FIG. 6, it may also be possible to form only one of the insulating coatings 153 and 154.

Next, a detailed configuration of the microwave radiation mechanism will be described.

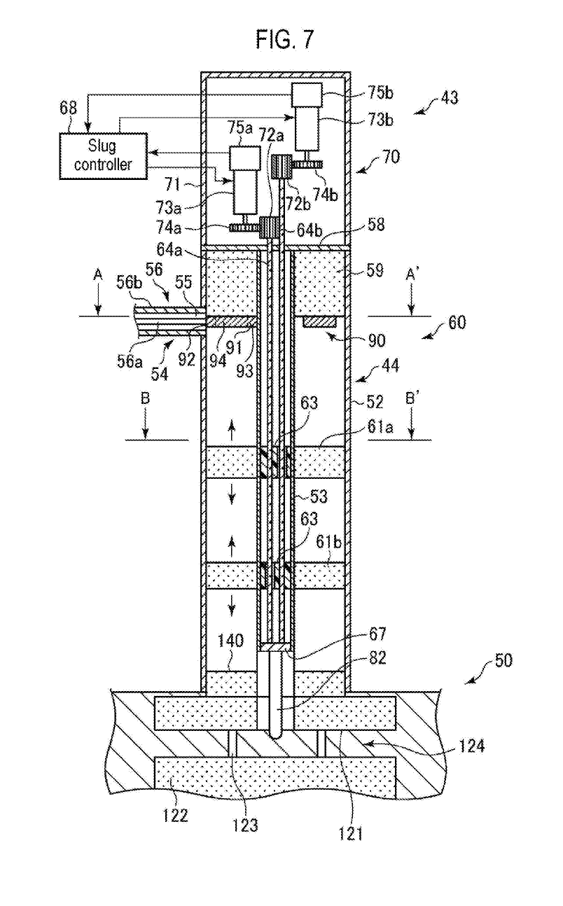

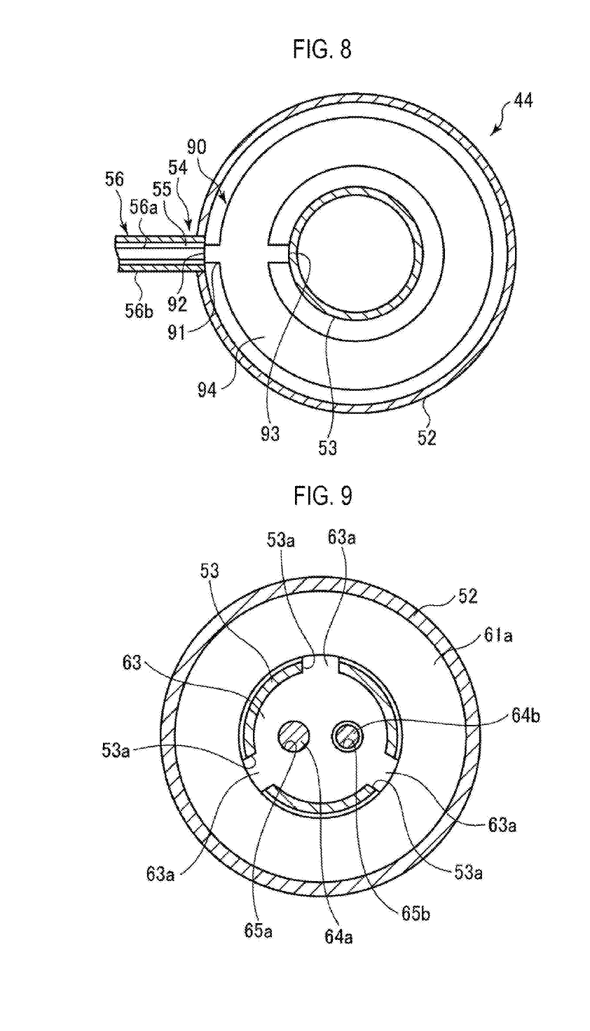

FIG. 7 is a sectional view illustrating the microwave radiation mechanism 43. FIG. 8 is a transversal cross-sectional view taken along line A-A′ in FIG. 7, illustrating a power feeding mechanism of the microwave radiation mechanism 43. FIG. 9 is a transversal cross-sectional view taken along line B-B′ in FIG. 7, illustrating a slug and a sliding member in the microwave radiation mechanism 43.

As described above, the microwave radiation mechanism 43 includes the tuner 60. The tuner 60 includes a microwave transmission channel 44 formed by a cylindrical outer conductor 52 and a cylindrical inner conductor 53 disposed in the center of the outer conductor 52, which are coaxially arranged, and first and second slags 61a and 61b which are configured to vertically move between the outer conductor 52 and the inner conductor 53. The first slag 61a is disposed in the upper side and the second slag 61b is disposed in the lower side. The inner conductor 53 corresponds to a power feeding side and the outer conductor 52 corresponds to a ground side. Upper ends of the outer conductor 52 and the inner conductor 53 are connected to a reflective plate 58, and lower ends thereof are connected to the slot antenna 124. The first and second slags 61a and 61b have the function of matching the impedance of a load (plasma) inside the chamber 1 to the characteristic impedance of the microwave power supply 31 in the microwave output part 30 as these slags are moved.

A power feeding mechanism 54 for feeding a microwave (electromagnetic wave) from the amplifying part 42 is installed at a proximal end side of the microwave transmission channel 44. The power feeding mechanism 54 includes a microwave power introduction port 55 which is formed in a lateral side of the microwave transmission channel 44 (the outer conductor 52) to introduce microwave power therethrough. The microwave power introduction port 55 is connected to a coaxial line 56 used as a power feeding line through which the microwave amplified at the amplifying part 42 is supplied. The coaxial line 56 is composed of an inner conductor 56a and an outer conductor 56b. A leading end of the inner conductor 56a of the coaxial line 56 is connected to a feed antenna 90 which horizontally expands toward the interior of the outer conductor 52.

The feed antenna 90 is formed, for example by cutting a metal plate such as aluminum and then putting the cut metal plate into a mold of a dielectric member such as Teflon®. A slow-wave member 59 made of a dielectric such as Teflon® and configured to shorten an effective wavelength of a reflected wave is interposed between the reflective plate 58 and the feed antenna 90. In this case, by optimizing a distance from the feed antenna 90 to the reflective plate 58 and reflecting an electromagnetic wave, which is radiated from the feed antenna 90, at the reflective plate 58, a maximum amount of the electromagnetic wave is transmitted into the microwave transmission channel 44 of the coaxial structure.

As shown in FIG. 8, the feed antenna 90 includes an antenna body 91 and a ring-shaped reflective part 94. The antenna body 91 includes a first pole 92 which is connected to the inner conductor 56a of the coaxial line 56 in the microwave power introduction port 55 and is supplied thereto with the electromagnetic wave, and a second pole 93 for radiating the supplied electromagnetic wave. The ring-shaped reflective part 94 is formed to extend along an outer side of the inner conductor 53 from both sides of the antenna body 91. The feed antenna 90 is configured to form a standing wave with the electromagnetic wave incident into the antenna body 91 and an electromagnetic wave reflected at the reflective part 94. The second pole 93 of the antenna body 91 is in contact with the inner conductor 53.

When the feed antenna 90 radiates the microwave (electromagnetic wave) so that the microwave power is fed into a space between the outer conductor 52 and the inner conductor 53. Then, the microwave power supplied into the power feeding mechanism 54 propagates toward the microwave radiation member 50.

Two slag moving shafts 64a and 64b for slag movement are place in an internal space of the inner conductor 53. Each of the slag moving shafts 64a and 64b are composed of a trapezoidal threaded rod extending in a longitudinal direction of the inner conductor 53.

As shown in FIG. 9, the first slag 61a made of dielectric has an annular shape, and a slip member 63 made of a slippery resin is fitted into the first slag 61a. The slip member 63 is formed with a screw hole 65a with which the slag moving shaft 64a is screwed, and a through hole 65b into which the slag moving shaft 64b is inserted. Likely, the second slag 61b has also a screw hole 65a and a through hole 65b. However, contrary to the first slag 61a, the screw hole 65a is screwed with the slag moving shaft 64b and the slag moving shaft 64a is inserted into the through hole 65b. With this configuration, the first slag 61a is moved up and down as the slag moving shaft 64a is rotated, while the second slag 61b is moved up and down as the slag moving shaft 64b is rotated. That is to say, the first slag 61a and the second slag 61b are moved up and down by means of a screw mechanism composed of the slag moving shafts 64a and 64b and the slip member 63.

Three slits 53a are formed at equal intervals in the inner conductor 53 in the longitudinal direction. On the other hand, the slip member 63 has three projections 63a formed at equal intervals to correspond to these slits 53a. The slip member 63 is fitted into the first slag 61a and the second slag 61b while the projections 63a are brought into contact with inner peripheries of the first and second slags 61a and 61b. An outer peripheral surface of the slip member 63 is in contact with an inner peripheral surface of the inner conductor 53 with no margin. Therefore, when the slag moving shafts 64a and 64b are rotated, the slip member 63 is moved up and down while sliding along the inner conductor 53. That is to say, the inner peripheral surface of the inner conductor 53 acts as a sliding guide for guiding the first and second slags 61a and 61b.

The slag moving shafts 64a and 64b extend up to the slag driver 70 through the reflective plate 58. A bearing (not shown) is interposed between the slag moving shafts 64a and 64b and the reflective plate 58.

The slag driver 70 includes a housing 71 into which the slag moving shafts 64a and 64b extend. Gears 72a and 72b are respectively installed on upper ends of the slag moving shafts 64a and 64b. In addition, the slag driver 70 includes a motor 73a for rotating the slag moving shaft 64a and a motor 73b for rotating the slag moving shaft 64b. A gear 74a is attached to a shaft of the motor 73a and a gear 74b is attached to a shaft of the motor 73b. Thus, the gear 74a engages with the gear 72a and the gear 74b engages with the gear 72b. Therefore, the slag moving shaft 64a is rotated by the motor 73a through the gears 74a and 72a, and the slag moving shaft 64b is rotated by the motor 73b through the gears 74b and 72b. The motors 73a and 73b are, for example, stepping motors.

The slag moving shaft 64b is longer than the slag moving shaft 64a so that the slag moving shaft 64b is extended to a higher level. Therefore, since vertical positions of the gears 72a and 72b are offset and the motors 73a and 73b are also vertically offset, a space for a power transmission mechanism composed of the motors and gears may be small. Encoders 75a and 75b, which are directly connected to output shafts of the respective motors 73a and 73b to detect positions of the first and second slags 61a and 61b, are installed on the motors 73a and 73b, respectively.

The positions of the first and second slags 61a and 61b are controlled by a slag controller 68. Specifically, based on an input terminal impedance value detected by an impedance detector (not shown) and position information of the first and second slags 61a and 61b detected by the encoders 75a and 75b, the slag controller 68 sends control signals to the motors 73a and 73b to control the positions of the first and second slags 61a and 61b. In this way, an impedance adjustment is performed. The slag controller 68 executes an impedance matching such that a resistance of a terminal becomes, for example, 50 Ω. If only one of the two slags 61a and 61b is moved, the impedance draws a trajectory which passes through the origin of the Smith chart. If both of the two slags 61a and 61b are moved, only a phase is rotated.

An impedance adjusting member 140 is installed at a leading end of the microwave transmission channel 44. The impedance adjusting member 140 may be made of dielectric and is configured to adjust the impedance of the microwave transmission channel 44 based on a dielectric constant of the dielectric. A cylindrical member 82 is disposed on a bottom plate at the leading end of the microwave transmission channel 44. The cylindrical member 82 is connected to the slot antenna part 124. The slow-wave member 121 can adjust the phase of the microwave by its thickness. The thickness of the slow-wave member 121 is adjusted such that the upper surface (the microwave radiation surface) of the slot antenna part 124 corresponds to a “belly” of the standing wave. This allows reflection to be at a minimum and microwave radiation energy to be at a maximum.

In this embodiment, the main amplifier 48, the tuner 60, and the slot antenna part 124 are arranged adjacent to each other. A combination of the tuner 60 and the slot antenna part 124 constitutes a lumped constant circuit which exists in a ½ wavelength. In addition, a combined resistance of the slot antenna part 124 and the slow-wave member 121 is set to 50 Ω. Thus, the tuner 60 can directly tune a plasma load, which makes it possible to transfer energy to the plasma with high efficiency.

### Operation of Plasma Processing Apparatus

Next, an operation of the plasma processing apparatus 100 configured as above will be described.

First, a wafer W is loaded into the chamber 1 and is mounted on the susceptor 11. Then, a plasma generation gas such as an Ar gas, or a first gas to be decomposed with high energy is discharged from the first gas supply source 22 into the chamber 1 via the gas supply pipe 111 and the first gas introduction part 21 of the microwave radiation member 50.

Specifically, a plasma generation gas or a process gas is introduced from the first gas supply source 22 through the gas supply pipes 111 and is supplied to the inner gas diffusion space 141, the middle gas diffusion space 142 and the outer gas diffusion space 143 of the first gas introduction part 21 through the gas introduction holes 144, 146 and 148. The plasma generation gas or the process gas is discharged into the chamber 1 through the gas discharge holes 145, 147 and 149.

In the meantime, the microwaves outputted from the microwave output part 30 of the microwave plasma source 2 are distributed by the distributor 34. Thereafter, the microwaves are amplified by the amplifier parts 42 of the microwave transmission/radiation part 40 and are supplied to the respective microwave radiation mechanisms 43. Specifically, the microwaves coming from each of the amplifier parts 42 are fed into the tuner 60 through the power feeding mechanism 54 and are transmitted as TEM waves through the tuner 60. Impedance matching occurs in the course of transmission. Then, the microwaves transmitted through the tuner 60 are introduced into the microwave radiation plate 50 and are transmitted through the slow-wave member 121. Thereafter, the microwaves are transmitted to the slots 123 of the slot antenna 124 and are converted to a mode of TE waves. Subsequently, the microwaves are transmitted through the microwave transmission member 122 and are radiated into the chamber 1 from the microwave radiation surface, i.e., the lower surface of the microwave transmission member 122. Thus, surface waves are formed on the surface of the microwave transmission member 122.

The first gas introduced from the first gas introduction part 21 into the chamber 1 is converted to plasma by the surface waves, whereby surface wave plasma is generated in the space of the chamber 1. In this case, the electric field intensity within the chamber 1 when the microwaves are radiated from the microwave radiation surface is largest on the lower surface of the microwave transmission member 122, i.e., the microwave radiation surface. Thus, a high electric field region is formed just below the microwave radiation surface.

In this regard, if the perforated plate 151 is not provided and if a high electric field region is formed within the chamber 1 by radiating the microwaves from the plurality of microwave radiation mechanisms, there may be a case where abnormal electrical discharge occurs in the sidewall or the like within the chamber 1 so that the plasma is destabilized. In addition, there may be a case where the plasma ignitability becomes insufficient.

In contrast, in this embodiment, within the chamber 1, the perforated plate 151 having a ground potential is provided in the high electric field formation region existing just below the microwave radiation plate 50 having the microwave radiation surface. Therefore, when the microwaves are radiated from the microwave radiation mechanisms 43, the space 152 defined by the microwave radiation plate 50 and the perforated plate 151 becomes a high electric field region, whereby plasma is generated in the space 152. At this time, the surface waves formed just below the microwave radiation surface are confined in the space 152 which is a high electric field region. Thus, the power absorption efficiency of the plasma can be kept in the space 152 at a high level. Accordingly, stable electrical discharge easily occurs in the space 152, which makes it difficult for abnormal electrical discharge to occur. By confining the surface waves in the space 152 and keeping the power absorption efficiency of the plasma at a high level in this way, it is possible to reduce the plasma ignition power and to improve the plasma ignitability.

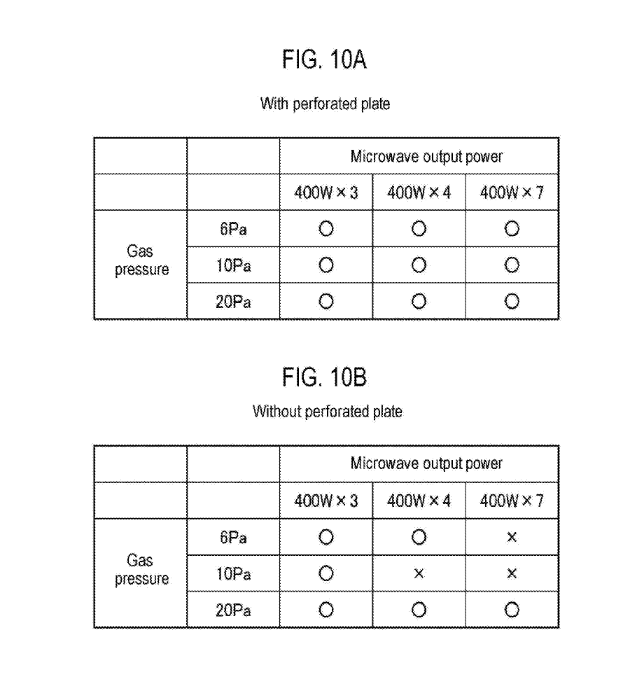

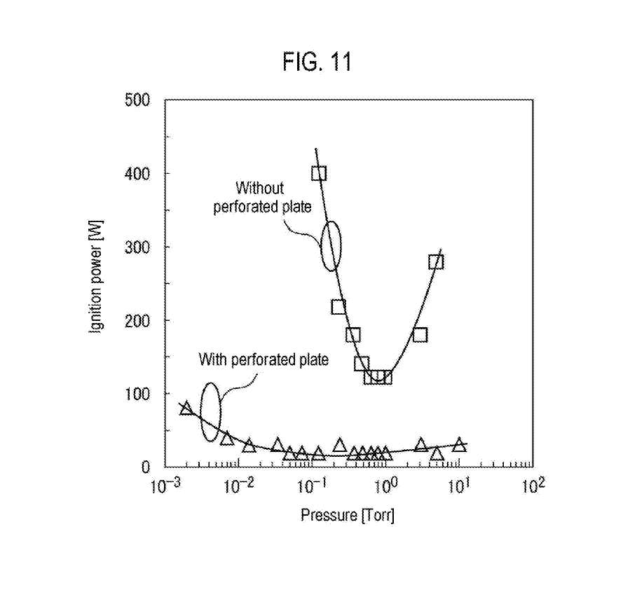

The results of verification thereof will be described with reference to FIGS. 10A, 10B and 11.

FIGS. 10A and 10B are views showing the presence or absence of abnormal electrical discharge in the case where surface wave plasma is formed by using the plasma processing apparatus shown in FIG. 1 and provided with the perforated plate and a plasma processing apparatus not provided with the perforated plate and by changing the microwave power and the internal pressure of the chamber. FIG. 10A shows a case where the perforated plate is provided and FIG. 10B shows a case where the perforated plate is not provided. The microwave power was set at 400 W per one microwave radiation mechanism and was adjusted by changing the number of the microwave radiation mechanisms for outputting microwaves. In FIGS. 10A and 10B, ∘ indicates a case where abnormal electrical discharge did not occur, and x indicates a case where abnormal electrical discharge has occurred.

As shown in FIGS. 10A and 10B, if the perforated plate is not provided, abnormal electrical discharge occurs at the low pressure side and at the high power side. In contrast, it can be noted that if the perforated plate is provided, abnormal electrical discharge does not occur under any condition and stable plasma is generated.

FIG. 11 is a view showing the ignition power (plasma-igniting power) when the internal pressure of a chamber is changed by using the plasma processing apparatus shown in FIG. 1 and provided with the perforated plate and a plasma processing apparatus not provided with the perforated plate.

As shown in FIG. 11, the ignition power can be made small by providing the perforated plate. It can be noted that this effect is particularly conspicuous at the low pressure side.

In this way, the surface wave plasma generated in the space 152, i.e., the high electric field region, reaches the region existing under the perforated plate 151 through the holes 151a of the perforated plate 151. A second gas such as a process gas to be supplied without decomposition as far as possible or the like is supplied from the second gas supply source 24 to the region existing under the perforated plate 151 through the second gas introduction part 23. The second gas discharged from the second gas introduction part 23 is excited by the plasma of the first gas coming from the space 152 through the perforated plate 151. In this case, the discharge position of the second gas is spaced apart from the microwave radiation surface and is a position where the electric field intensity is lower than that of the space 152 which is a high electric field region. Therefore, the second gas is excited under a state in which unnecessary decomposition is suppressed. Being excited by the second gas, the wafer W is subjected to a specified plasma process, for example, a film forming process or an etching process.

### Second Embodiment

Next, descriptions will be made on a second embodiment.

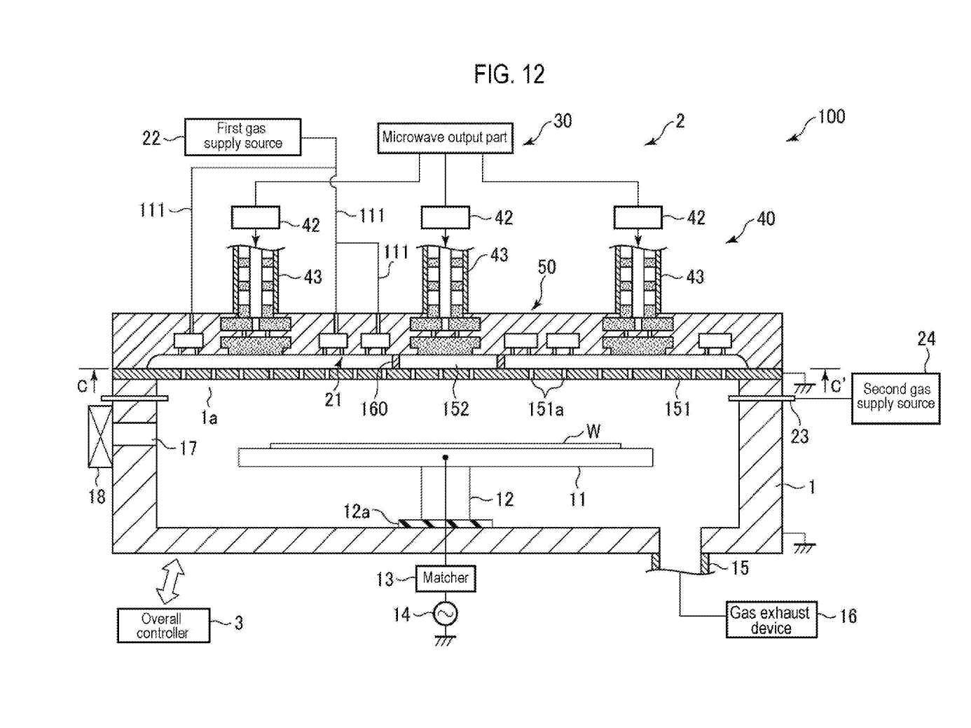

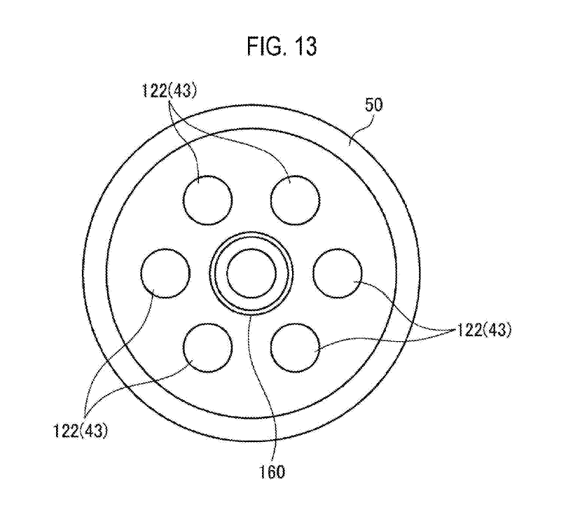

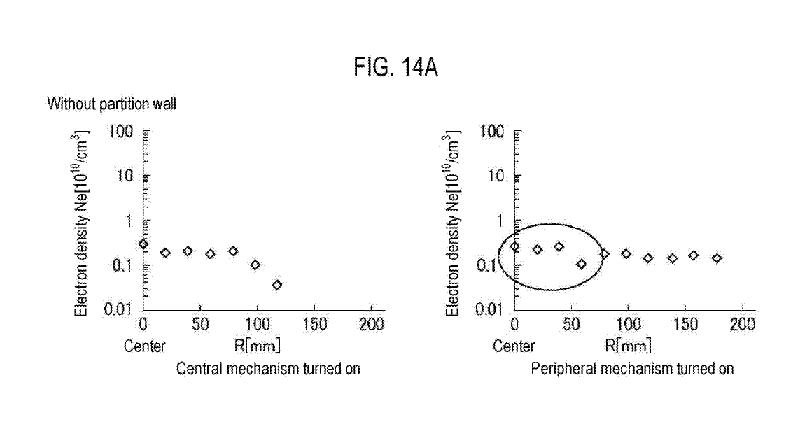

FIG. 12 is a sectional view illustrating a schematic configuration of a plasma processing apparatus according to a second embodiment of the present disclosure. FIG. 13 is a sectional view of the plasma processing apparatus taken along line C-C′ in FIG. 12.

The second embodiment differs from the first embodiment only in that the second embodiment includes a partition wall 160 configured to divide a space corresponding to the central microwave radiation mechanism 43 and a space corresponding to the peripheral microwave radiation mechanisms 43 in the space 152 used as a plasma generation space formed in a high electric field region. Other configurations are the same as those of the first embodiment. Accordingly, the same components as those of the first embodiment will be designated by like reference numerals with the descriptions thereof omitted.

In the first embodiment, the plasma is supplied to the wafer W through the perforated plate 151. It is therefore difficult for the microwave radiation mechanisms 43 to perform control of a plasma density (e.g., control of lowering a central plasma density and increasing a peripheral plasma density). In contrast, in this embodiment, the partition wall 160 made of an electrically conductive material and configured to divide the space 152 into a space corresponding to the central microwave radiation mechanism 43 and a space corresponding to the six peripheral microwave radiation mechanisms 43 is provided in a state in which the partition wall 160 is electrically connected to the perforated plate 151. Thus, the electric field intensity can be controlled by individually forming electric fields with the central microwave radiation mechanism 43 and the six peripheral microwave radiation mechanisms 43. This makes it possible to improve the controllability of plasma densities in a central region and a peripheral region. As the electrically conductive material of which the partition wall 160 is made, it may be possible to appropriately use metal having good electric conductivity such as aluminum, copper or the like.

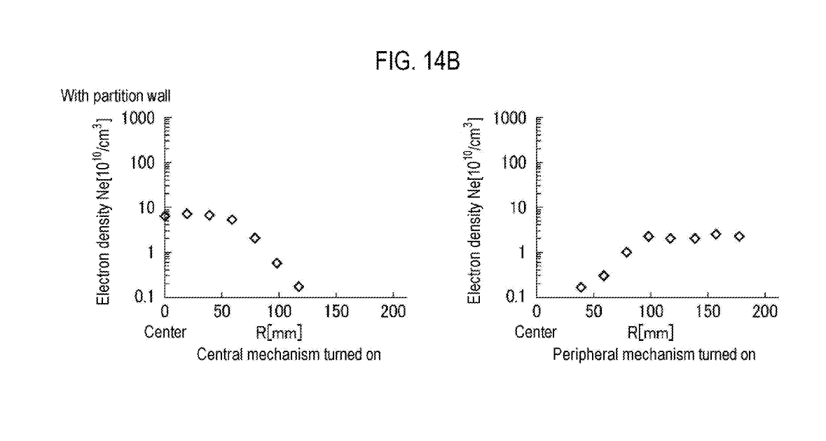

The results of verification of the foregoing descriptions are shown in FIGS. 14A and 14B.

FIGS. 14A and 14B are views showing the evaluation results of an electron density distribution in the diametrical direction of the chamber in the case where only the central microwave radiation mechanism is turned on by using the plasma processing apparatus shown in FIG. 1 and not provided with the partition wall and the plasma processing apparatus shown in FIG. 12 and provided with the partition wall and in the case where only the six peripheral microwave radiation mechanisms are turned on by using the plasma processing apparatus shown in FIG. 1 and not provided with the partition wall and the plasma processing apparatus shown in FIG. 12 and provided with the partition wall.

As shown in FIG. 14A, if the partition wall is not provided, the electron density is high only in the central region of the chamber 1 when only the central microwave radiation mechanism is turned on. However, the electron density in the central region where one does not wish to generate plasma becomes equal to the electron density in the peripheral region when only the peripheral microwave radiation mechanisms are turned on. It can be noted that the electron density cannot be sufficiently controlled. In contrast, as shown in FIG. 14B, if the partition wall is provided, it can be noted that the electron density can be controlled both when only the central microwave radiation mechanism is turned on and when only the peripheral microwave radiation mechanisms are turned on.

The partition wall 160 may be formed in a perforated structure having a plurality of holes formed therein, such as a mesh structure, a punched structure or the like. By forming the partition wall 160 in the perforated structure, it is possible to supply a first gas such as a plasma generation gas or the like from one space to the other space divided by the partition wall 160. This provides a merit in that even if there is a restraint that the first gas can be supplied to only one space, it is possible to generate plasma in the entirety of the space 152.

In some embodiments, in order to effectively achieve the aforementioned electric field control function in the case where the partition wall 160 is formed in the perforated structure, a diameter of the holes formed in the partition wall 160 may be formed at such a size as not to allow an electric field waveform to pass through the holes. For example, in the case where the frequency of microwaves is set at 860 MHz, the wavelength λ is 349 mm and the length (λ′) of one wavelength of an electric field waveform in the vicinity of the partition wall 160 is about 24 mm. In order to assure that the electric field waveform is kept in a confined state without passing through the holes of the partition wall 160, it is necessary to set the diameter of the holes at λ′/8 or less. Therefore, the diameter of the holes, through which the electric field waveform does not pass when the frequency of microwaves is 860 MHz, is 24/8=3 mm or less. The frequency f of microwaves and the wavelength λ′ of the electric field waveform are in an inversely proportional relationship with each other (μ′∝1/f). Thus, the diameter d of the holes of the partition wall 160 in the case of using the frequency as a variable has a relationship of 1/860 MHz: 3 mm=1/f: d. The diameter d in the case of using the frequency f as a variable can be represented by the following general formula (1).

d=2.58×10⁹/f (1)

Accordingly, the diameter d of the holes when the partition wall 160 is formed in a perforated structure may be 2.58×10⁹/f or less.

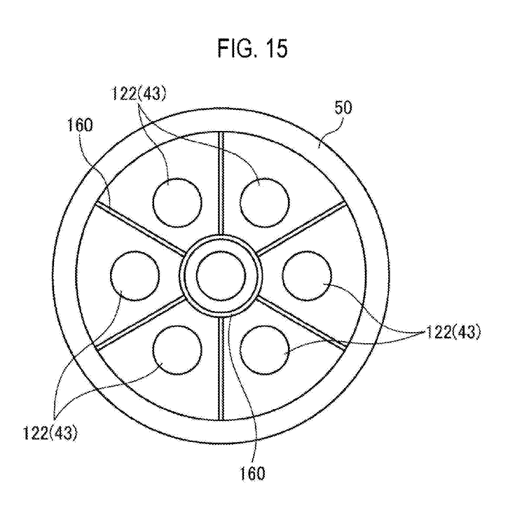

In the example described above, in the space 152, only the space corresponding to the central microwave radiation mechanism has been described to be partitioned from the space corresponding to the six peripheral microwave radiation mechanisms. In some embodiments, as shown in FIG. 15, the spaces corresponding to all the microwave radiation mechanisms 43 may be partitioned by the partition wall 160.

### Other Applications

While the embodiments of the present disclosure have been described above with reference to the accompanying drawings, the present disclosure is not limited to the above-described two embodiments but may be differently modified within the scope of the spirit of the present disclosure.

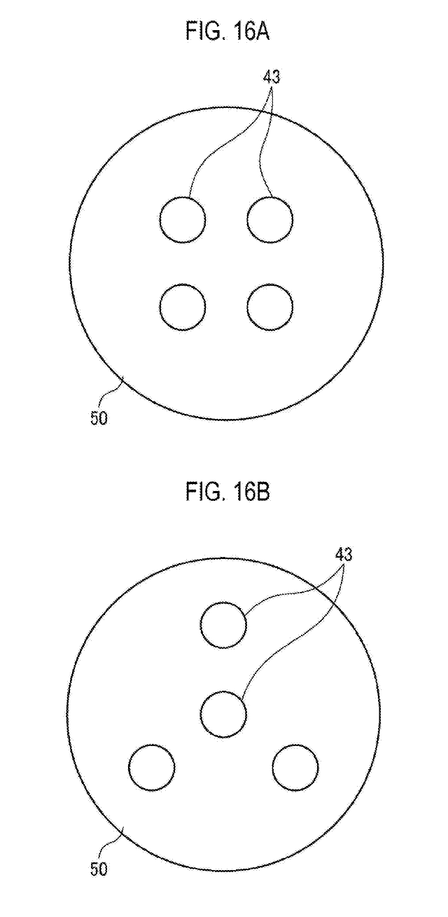

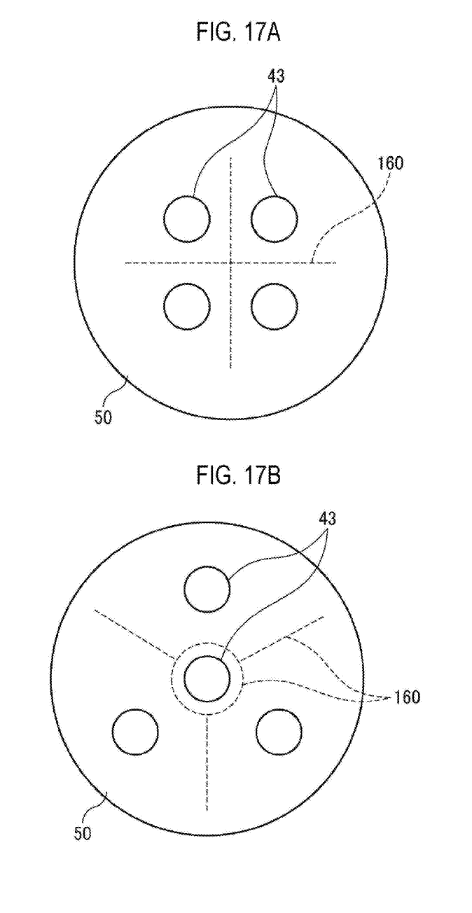

As an example, in the above embodiments, there has been shown an example in which one microwave radiation mechanism is provided in the region corresponding to the center of the chamber and six microwave radiation mechanisms are provided in the region corresponding to the periphery of the chamber. However, the number and arrangement of the microwave radiation mechanisms are not limited thereto. The present disclosure can be applied as long as a plurality of microwave radiation mechanisms is provided. Other arrangement examples of the microwave radiation mechanisms may include the ones shown in FIGS. 16A and 16B. In the case where the microwave radiation mechanisms are arranged as shown in FIGS. 16A and 16B, the partition wall 160 may be disposed as shown in FIGS. 17A and 17B.

Furthermore, the configurations of the microwave output part and the microwave transmission/radiation part are not limited to those of the above embodiments. As an example, the phase shifter may be omitted if there is no need to control the directivity of the microwaves radiated from the slot antenna or to convert the microwaves to circularly-polarized waves. Moreover, the configurations of the microwave radiation mechanisms are not limited to those of the aforementioned embodiments.

In addition, while in the aforementioned embodiments, a film forming apparatus and an etching processing apparatus has been described as examples of the plasma processing apparatus, the present disclosure is not limited thereto. In some embodiments, the present disclosure may be applied to different plasma processes such as an oxynitride film forming process including an oxidizing process and a nitriding process, an ashing process, or the like. Furthermore, the object to be processed is not limited to the semiconductor wafer W but may be other substrates such as an FPD (Flat Panel Display) substrate represented by an LCD (Liquid Crystal Display) substrate, a ceramic substrate, and the like.

According to the present disclosure, a perforated plate set at a ground potential is provided in a high electric field formation region existing just below a microwave radiation surface. Therefore, when microwaves are radiated from microwave radiation mechanisms, a space defined by the microwave radiation surface and the perforated plate becomes a high electric field region so that plasma is generated in the space. At this time, surface waves formed just below the microwave radiation surface are confined in the space defined by the microwave radiation surface and the perforated plate, which is the high electric field region. Thus, a power absorption efficiency of the plasma can be kept high in the space. Accordingly, stable electrical discharge easily occurs in the space making it difficult for abnormal electrical discharge to occur. By confining the surface waves in the space defined by the microwave radiation surface and the perforated plate and keeping the power absorption efficiency of the plasma high in this way, it is possible to reduce a plasma ignition power and to improve a plasma ignitability.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A microwave plasma source for radiating microwaves into a chamber of a plasma processing apparatus to generate surface wave plasma, comprising:
a plurality of microwave radiation mechanisms provided in a ceiling wall of the chamber and configured to radiate microwaves into the chamber; and
a perforated plate provided in a high electric field formation region which becomes a high electric field region when the microwaves are radiated from microwave radiation surfaces of the microwave radiation mechanisms into the chamber and which exists just below the microwave radiation surfaces, the perforated plate having a plurality of holes formed therein, the perforated plate set at a ground potential and made of an electrically conductive material, wherein the perforated plate has a function of confining surface waves formed just below the microwave radiation surfaces when the microwaves are radiated from the microwave radiation mechanism, in a space surrounded by the microwave radiation surfaces and the perforated plate and configured to become the high electric field region, and a function of keeping high a power absorption efficiency of plasma generated in the space.

2. The source of claim 1, wherein a distance between the microwave radiation surfaces and an upper surface of the perforated plate falls within a range of 2 to 30 mm

3. The source of claim 1, further comprising:
an insulating coating provided in a portion corresponding to a lateral side of the chamber in the space.

4. The source of claim 1, further comprising:
an insulating coating provided on an upper surface of the perforated plate.

5. The source of claim 1, wherein one of the plurality of microwave radiation mechanisms is disposed in a central region of the ceiling wall of the chamber and the remaining microwave radiation mechanisms are disposed in a peripheral region of the ceiling wall of the chamber.

6. The source of claim 1, further comprising:
a partition wall configured to divide the space into a space corresponding to at least one of the plurality of microwave radiation mechanisms and a space corresponding to the remaining microwave radiation mechanisms, the partition wall electrically connected to the perforated plate and made of an electrically conductive material.

7. The source of claim 6, wherein one of the plurality of microwave radiation mechanisms is disposed in a central region of the ceiling wall of the chamber and the remaining microwave radiation mechanisms are disposed in a peripheral region of the ceiling wall of the chamber, the partition wall configured to divide the space into a space corresponding to the microwave radiation mechanism disposed in the central region and a space corresponding to the microwave radiation mechanisms disposed in the peripheral region.

8. The source of claim 6, wherein the partition wall is configured to divide the space into spaces corresponding to all the plurality of microwave radiation mechanisms.

9. The source of claim 6, wherein the partition wall is formed in a perforated structure having a plurality of holes formed at such a size as not to allow an electric field waveform to pass through the holes.

10. The source of claim 9, wherein a diameter d of each of the holes is 2.58×10⁹/f or less where f is a frequency of the microwaves.

11. A plasma processing apparatus, comprising:
a chamber configured to accommodate a target substrate;
a mounting table configured to mount the substrate thereon within the chamber;
a gas supply mechanism configured to supply a gas into the chamber; and
a microwave plasma source configured to radiate microwaves into the chamber to form surface wave plasma, the plasma processing apparatus configured to perform a plasma process on the target substrate using the surface wave plasma,
wherein the microwave plasma source includes:
a plurality of microwave radiation mechanisms provided in a ceiling wall of the chamber and configured to radiate microwaves into the chamber; and
a perforated plate provided in a high electric field formation region which becomes a high electric field region when the microwaves are radiated from microwave radiation surfaces of the plurality of microwave radiation mechanisms into the chamber and which exists just below the microwave radiation surfaces, the perforated plate having a plurality of holes form therein, the perforated plate set at a ground potential and made of an electrically conductive material,
wherein the perforated plate has a function of confining surface waves formed just below the microwave radiation surfaces when the microwaves are radiated from plurality of the microwave radiation mechanism, in a space surrounded by the microwave radiation surfaces and the perforated plate and configured to become the high electric field region, and a function of keeping high a power absorption efficiency of plasma generated in the space.

12. The apparatus of claim 11, wherein a distance between the microwave radiation surfaces and an upper surface of the perforated plate falls within a range of 2 to 30 mm

13. The apparatus of claim 11, further comprising:
an insulating coating provided in a portion corresponding to a lateral side of the chamber in the space.

14. The apparatus of claim 11, further comprising:
an insulating coating provided on an upper surface of the perforated plate.

15. The apparatus of claim 11, wherein one of the plurality of microwave radiation mechanisms is disposed in a central region of the ceiling wall of the chamber and the remaining microwave radiation mechanisms are disposed in a peripheral region of the ceiling wall of the chamber.

16. The apparatus of claim 11, further comprising:
a partition wall configured to divide the space into a space corresponding to at least one of the plurality of microwave radiation mechanisms and a space corresponding to the remaining microwave radiation mechanisms, the partition wall electrically connected to the perforated plate and made of an electrically conductive material.

17. The apparatus of claim 16, wherein one of the plurality of microwave radiation mechanisms is disposed in a central region of the ceiling wall of the chamber and the remaining microwave radiation mechanisms are disposed in a peripheral region of the ceiling wall of the chamber, the partition wall configured to divide the space into a space corresponding to the microwave radiation mechanism disposed in the central region and a space corresponding to the microwave radiation mechanisms disposed in the peripheral region.

18. The apparatus of claim 16, wherein the partition wall is configured to divide the space into spaces corresponding to all the plurality of microwave radiation mechanisms.

19. The apparatus of claim 16, wherein the partition wall is formed in a perforated structure having a plurality of holes formed at such a size as not to allow an electric field waveform to pass through the holes.

20. The apparatus of claim 19, wherein a diameter d of each of the holes is 2.58×10⁹/f or less where f is a frequency of the microwaves.
